(19) United States
(12) Patent Application Publication
(10) Pub. No.: US 2025/0008654 A1
(43) Pub. Date: Jan. 2, 2025

(54) METHODS AND APPARATUS FOR MANUFACTURING AN ELECTRONIC APPARATUS

(71) Applicant: CORNING INCORPORATED, Corning, NY (US)

(72) Inventors: Sean Matthew Garner, Elmira, NY (US); Mandakini Kanungo, Ithaca, NY (US); Rajesh Vaddi, Horseheads, NY (US)

(21) Appl. No.: 18/710,331

(22) PCT Filed: Nov. 8, 2022
(86) PCT No.: PCT/US2022/049196

§ 371 Date: May 15, 2024

Related U.S. Application Data
(60) Provisional application No. 63/281,920, filed on Nov. 22, 2021.

(51) Int. Cl. H05K 1/11; H05K 1/09

(52) U.S. Cl. CPC H05K 1/117; H05K 1/09; H05K 2201/0108

(57) ABSTRACT

An electronic apparatus includes a substrate including a first major surface, a second major surface, and an edge surface extending between the major surfaces. A first electrode is attached to the first major surface and a second electrode is attached to the second major surface. A first surface interconnect is electrically connected to the first electrode. A first extension portion extends beyond an edge plane. A second surface interconnect is electrically connected to the second electrode and includes a second extension portion extending beyond the edge plane. An anisotropic conductor defines a current path between the first electrode and the second electrode. The anisotropic conductor is attached to the edge surface and extends between the first extension portion and the second extension portion such that the current path extends along the first major surface, edge surface, and the second major surface. Methods of manufacturing an electronic apparatus are provided.

### CROSS-REFERENCE TO RELATED APPLICATIONS

This application claims the benefit of priority under 35 U.S.C. § 119 of U.S. Provisional Application Ser. No. 63/281,920, filed on Nov. 22, 2021, the content of which is relied upon and incorporated herein by reference in its entirety.

### FIELD

The present disclosure relates generally to methods for manufacturing an electronic apparatus and, more particularly, to methods for manufacturing an electronic apparatus comprising an anisotropic conductor.

### BACKGROUND

It is known to fabricate an electronic device on a substrate. The electronic device can be positioned on a first major surface of the substrate and a first electrode can be positioned on the first major surface electrically connected to the electronic device. A second electrode can be positioned on a second major surface of the substrate. However, depending on the geometry of the substrate, connecting the first electrode to the second electrode can be time-consuming and lead to a shortened lifespan of the electronic device. In addition, inconsistent electric current transmission can occur due to a poor electrical connection between the electrodes.

### SUMMARY

The following presents a simplified summary of the disclosure to provide a basic understanding of some aspects described in the detailed description.

In aspects, an electronic apparatus can comprise a substrate comprising a first major surface, a second major surface, and an edge surface extending between the major surfaces. An anisotropic conductor can be attached to the edge surface and can define an electrically-conductive path between the first major surface and the second major surface. The anisotropic conductor can be electrically-conductive in a first direction (e.g., around the edge surface) but can act as an electrical insulator in a second direction (e.g., parallel to the edge surface and the first major surface). Accordingly, the anisotropic conductor can cover the edge surface of the substrate and form a plurality of electrically-conductive paths between the major surfaces, while electrically-isolating the electrically-conductive paths from one another.

In aspects, an electronic apparatus can comprise a substrate comprising a first major surface, a second major surface, and an edge surface extending between the first major surface and the second major surface. The electronic apparatus can comprise a first electrode attached to the first major surface. The electronic apparatus can comprise a second electrode attached to the second major surface. The electronic apparatus can comprise a first surface interconnect electrically connected to the first electrode and comprising a first extension portion extending beyond an edge plane along which the edge surface extends. The electronic apparatus can comprise a second surface interconnect electrically connected to the second electrode and comprising a second extension portion extending beyond the edge plane. The electronic apparatus can comprise an anisotropic conductor defining a current path between the first electrode and the second electrode. The anisotropic conductor can be attached to the edge surface and can extend between the first extension portion and the second extension portion such that the current path extends along the first major surface, the edge surface, and the second major surface.

In aspects, the current path can be spaced apart from the substrate and intersect the first extension portion, the second extension portion, and the anisotropic conductor.

In aspects, the substrate can comprise a thickness between the first major surface and the second major surface within a range from about 0.1 mm to about 1 mm.

In aspects, the anisotropic conductor can be spaced a first distance apart from the first electrode such that the first extension portion lies between the anisotropic conductor and the first electrode along the current path.

In aspects, the anisotropic conductor can be spaced a second distance apart from the second electrode such that the second extension portion lies between the anisotropic conductor and the second electrode along the current path.

In aspects, the first surface interconnect can be spaced apart from the first electrode, and a first anisotropic portion of the anisotropic conductor can extend between the first electrode and the first surface interconnect. The first anisotropic portion can electrically connect the first electrode and the first surface interconnect by defining a first path portion of the current path substantially perpendicular to the first major surface.

In aspects, the second surface interconnect can be spaced apart from the second electrode, and a second anisotropic portion of the anisotropic conductor can extend between the second electrode and the second surface interconnect. The second anisotropic portion can electrically connect the second electrode and the second surface interconnect by defining a second path portion of the current path substantially perpendicular to the second major surface.

In aspects, the first surface interconnect can comprise a first interconnect portion in contact with the first electrode and a second interconnect portion extending parallel to and spaced apart from the first electrode. A first anisotropic portion of the anisotropic conductor can extend between the first electrode and the second interconnect portion.

In aspects, the second surface interconnect can comprise a third interconnect portion in contact with the second electrode and a fourth interconnect portion extending parallel to and spaced apart from the second electrode. A second anisotropic portion of the anisotropic conductor can extend between the second electrode and the fourth interconnect portion.

In aspects, a first electrical resistance of the anisotropic conductor in a direction perpendicular to the first major surface can be less than about 1 ohm.

In aspects, a second electrical resistance of the anisotropic conductor in a direction parallel to the first major surface can be greater than about 1011 ohms.

In aspects, an electronic apparatus can comprise a substrate comprising a first major surface, a second major surface, and an edge surface extending between the first major surface and the second major surface. The electronic apparatus can comprise a first electrode attached to the first major surface and a second electrode attached to the second major surface. The electronic apparatus can comprise a first surface interconnect extending parallel to and spaced apart from the first electrode. The electronic apparatus can comprise a second surface interconnect extending parallel to and spaced apart from the second electrode. The electronic apparatus can comprise an anisotropic conductor defining a current path between the first electrode and the second electrode. The anisotropic conductor can comprise a first anisotropic portion extending between the first electrode and the first surface interconnect. The first anisotropic portion can electrically connect the first electrode and the first surface interconnect by defining a first path portion of the current path substantially perpendicular to the first major surface. The anisotropic conductor can comprise a second anisotropic portion extending between the second electrode and the second surface interconnect. The second anisotropic portion can electrically connect the second electrode and the second surface interconnect by defining a second path portion of the current path substantially perpendicular to the second major surface. The anisotropic conductor can comprise a third anisotropic portion attached to the edge surface and extending between the first surface interconnect and the second surface interconnect. The third anisotropic portion can electrically connect the first surface interconnect and the second surface interconnect by defining a third path portion of the current path along the edge surface.

In aspects, the first surface interconnect can comprise a first surface attached to the first anisotropic portion.

In aspects, the first surface interconnect can define a fourth path portion of the current path substantially parallel to the first major surface between the first path portion and the third path portion. The second surface interconnect can define a fifth path portion of the current path substantially parallel to the second major surface between the second path portion and the third path portion.

In aspects, the first surface interconnect can comprise a first extension portion extending beyond an edge plane along which the edge surface extends and the second surface interconnect can comprise a second extension portion extending beyond the edge plane.

In aspects, the third anisotropic portion can extend between the first extension portion and the second extension portion such that an axis intersects the first extension portion, the second extension portion, and the third anisotropic portion. The axis can be spaced apart from the substrate.

In aspects, methods of manufacturing an electronic apparatus can comprise forming a first electrode on a first major surface of a substrate. Methods can comprise forming a second electrode on a second major surface of the substrate. Methods can comprise forming an anisotropic conductor on an edge surface of the substrate. Methods can comprise forming a first surface interconnect electrically connected to the first electrode such that a first extension portion of the first surface interconnect extends beyond an edge plane along which the edge surface extends. Methods can comprise forming a second surface interconnect electrically connected to the second electrode such that a second extension portion of the second surface interconnect extends beyond the edge plane. The anisotropic conductor can electrically connect the first extension portion and the second extension portion such that a current path extending through the anisotropic conductor is substantially perpendicular to the first major surface.

In aspects, forming the anisotropic conductor can comprise generating a first electrical resistance of the anisotropic conductor in a direction perpendicular to the first major surface less than about 1 ohm and a second electrical resistance of the anisotropic conductor in a direction parallel to the first major surface greater than about 1011 ohms.

In aspects, forming the first surface interconnect can comprise maintaining a space between the first surface interconnect and the first electrode such that the first surface interconnect is not in contact with the first electrode and a first anisotropic portion of the anisotropic conductor extends between the first electrode and the first surface interconnect.

In aspects, forming the first surface interconnect can comprise contacting the first surface interconnect to the first electrode.

Additional features and advantages of the aspects disclosed herein will be set forth in the detailed description that follows, and in part will be clear to those skilled in the art from that description or recognized by practicing the aspects described herein, including the detailed description which follows, the claims, as well as the appended drawings. It is to be understood that both the foregoing general description and the following detailed description present aspects intended to provide an overview or framework for understanding the nature and character of the aspects disclosed herein. The accompanying drawings are included to provide further understanding and are incorporated into and constitute a part of this specification. The drawings illustrate various aspects of the disclosure, and together with the description explain the principles and operations thereof.

### BRIEF DESCRIPTION OF THE DRAWINGS

These and other features, aspects and advantages are better understood when the following detailed description is read with reference to the accompanying drawings, in which:

FIG. 1 illustrates a perspective of an electronic apparatus in accordance with aspects of the disclosure;

FIG. 2 illustrates a side view of the electronic apparatus in accordance with aspects of the disclosure;

FIG. 3 illustrates a side view of the electronic apparatus in accordance with aspects of the disclosure;

FIG. 4 illustrates a side view of the electronic apparatus in accordance with aspects of the disclosure;

FIG. 5 illustrates a side view of the electronic apparatus in accordance with aspects of the disclosure;

FIG. 6 illustrates a side view of the formation of electrodes on major surfaces of a substrate in accordance with aspects of the disclosure;

FIG. 7 illustrates a side view of the formation of an anisotropic conductor in accordance with aspects of the disclosure;

FIG. 8 illustrates a perspective of an electronic apparatus in accordance with aspects of the disclosure;

FIG. 9 illustrates a side view of the formation of surface interconnects in accordance with aspects of the disclosure; and

FIG. 10 illustrates a side view of the formation of surface interconnects in accordance with aspects of the disclosure.

### DETAILED DESCRIPTION

Aspects will now be described more fully hereinafter with reference to the accompanying drawings in which example aspects are shown. Whenever possible, the same reference numerals are used throughout the drawings to refer to the same or like parts. However, this disclosure may be embodied in many different forms and should not be construed as limited to the aspects set forth herein.

As used herein, the term “about” means that amounts, sizes, formulations, parameters, and other quantities and characteristics are not, and need not be, exact, but may be approximate and/or larger or smaller, as desired, reflecting tolerances, conversion factors, rounding off, measurement error and the like, and other factors known to those of skill in the art.

Ranges can be expressed herein as from “about” one value, and/or to “about” another value. When such a range is expressed, aspects include from the one value to the other value. Similarly, when values are expressed as approximations by use of the antecedent “about,” it will be understood that the value forms another aspect. It will be further understood that the endpoints of each of the ranges are significant both in relation to the other endpoint, and independently of the other endpoint.

Directional terms as used herein—for example up, down, right, left, front, back, top, bottom, upper, lower, etc.—are made only with reference to the figures as drawn and are not intended to imply absolute orientation.

Unless otherwise expressly stated, it is in no way intended that any methods set forth herein be construed as requiring that its steps be performed in a specific order, nor that with any apparatus, specific orientations be required. Accordingly, where a method claim does not actually recite an order to be followed by its steps, or that any apparatus claim does not actually recite an order or orientation to individual components, or it is not otherwise specifically stated in the claims or description that the steps are to be limited to a specific order, or that a specific order or orientation to components of an apparatus is not recited, it is in no way intended that an order or orientation be inferred in any respect. This holds for any possible non-express basis for interpretation, including: matters of logic relative to arrangement of steps, operational flow, order of components, or orientation of components; plain meaning derived from grammatical organization or punctuation, and; the number or type of aspects described in the specification.

As used herein, the singular forms “a,” “an” and “the” include plural references unless the context clearly dictates otherwise. Thus, for example, reference to “a” component includes aspects having two or more such components, unless the context clearly indicates otherwise.

The word “exemplary,” “example,” or various forms thereof are used herein to mean serving as an example, instance, or illustration. Any aspect or design described herein as “exemplary” or as an “example” should not be construed as preferred or advantageous over other aspects or designs. Furthermore, examples are provided solely for purposes of clarity and understanding and are not meant to limit or restrict the disclosed subject matter or relevant portions of this disclosure in any manner. It can be appreciated that a myriad of additional or alternate examples of varying scope could have been presented but have been omitted for purposes of brevity.

As used herein, the terms “comprising” and “including”, and variations thereof, shall be construed as synonymous and open-ended, unless otherwise indicated. A list of elements following the transitional phrases comprising or including is a non-exclusive list, such that elements in addition to those specifically recited in the list may also be present.

The terms “substantial,” “substantially,” and variations thereof as used herein are intended to represent that a described feature is equal or approximately equal to a value or description. For example, a “substantially planar” surface is intended to denote a surface that is planar or approximately planar. Moreover, “substantially” is intended to denote that two values are equal or approximately equal. In aspects, “substantially” may denote values within about 10% of each other, such as within about 5% of each other, or within about 2% of each other.

Modifications may be made to the instant disclosure without departing from the scope or spirit of the claimed subject matter. Unless specified otherwise, “first,” “second,” or the like are not intended to imply a temporal aspect, a spatial aspect, an ordering, etc. Rather, such terms are merely used as identifiers, names, etc. for features, elements, items, etc. For example, a first end and a second end generally correspond to end A and end B or two different or two identical ends or the same end.

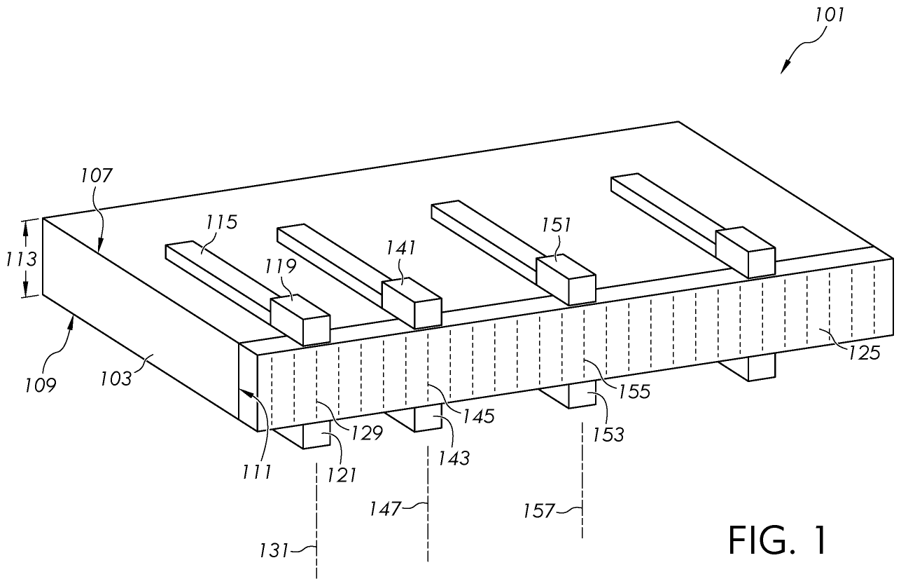

The present disclosure relates to an electronic apparatus and methods for manufacturing an electronic apparatus. For purposes of this application, the electronic apparatus can be employed in a variety of display and non-display applications comprising, but not limited to, liquid crystal displays (LCDs), electrophoretic displays (EPD), organic light emitting diode displays (OLEDs), plasma display panels (PDPs), microLED displays, miniLED displays, organic light emitting diode lighting, light emitting diode lighting, augmented reality (AR), virtual reality (VR), touch sensors, photovoltaics, foldable phones, antennas or other applications. FIG. 1 is a perspective view of a portion of an electronic apparatus 101 in accordance with aspects of the disclosure. The electronic apparatus 101 comprises a substrate 103. In aspects, the substrate 103 may comprise glass (e.g., a glass substrate), for example, one or more of soda-lime glass, borosilicate glass, alumino-borosilicate glass, alkali-containing glass, alkali-free glass, aluminosilicate, borosilicate, boroaluminosilicate, silicate, glass-ceramic, or other materials comprising glass. In aspects, the substrate 103 can comprise one or more of lithium fluoride (LiF), magnesium fluoride (MgF₂), calcium fluoride (CaF₂), barium fluoride (BaF₂), sapphire (Al₂O₃), zinc selenide (ZnSe), germanium (Ge) or other materials. The substrate 103 can alternatively comprise a ceramic, glass-ceramic, polymer, composite, metal, multi-layer stack, or a composite of materials. The substrate 103 can comprise several shapes, for example, square shapes, rectangular shapes, hexagonal shapes, irregular shapes, etc. The substrate 103 comprises a first major surface 107, a second major surface 109, and an edge surface 111 extending between the first major surface 107 and the second major surface 109. The substrate 103 may have one or more edge surfaces 111. In aspects, the substrate 103 can comprise a thickness 113 between the first major surface 107 and the second major surface 109 that is within a range from about 0.05 millimeters (mm) to about 3 mm, or within a range from about 0.1 mm to about 1 mm. The substrate 103 can have a dimension (length, width, or diameter for example) within a range from about 0.1 mm to about 3000 mm. For example, the dimension can be within a range from about 20 mm to about 1000 mm or from about 20 mm to about 500 mm or from about 50 mm to about 200 mm.

The electronic apparatus 101 can comprise an electronic device that may be positioned on the first major surface 107. As used herein, the term “positioned on” can comprise direct contact between the electronic device and the first major surface 107. In addition, the term “positioned on” can comprise indirect contact between the electronic device and the first major surface 107, for example, when an intermediate structure (e.g., conductive materials, dielectric materials, semiconductor materials, solder balls, etc.) is located between the electronic device and the first major surface 107. In aspects, the electronic device can comprise an opto-electronic device that can generate and/or emit light or control the emission, transmission, and/or reflection of light, and can comprise, for example, a micro light-emitting diode (microLEDs), an organic light-emitting diode (OLEDs), other types of light-emitting diodes, a thin-film transistor (TFT), a liquid crystal, electrophoretic, micro-mirror structure, micro-driver ICs, resistors, capacitors, etc. The electronic apparatus 101 is not limited to a single electronic device but, rather, may comprise a plurality of electronic devices spaced apart and positioned on the first major surface 107.

The electronic apparatus 101 comprises one or more electrodes that are electrically-conductive, for example, a first electrode 115. As used herein, the term “electrode” (e.g., first electrode 115) refers to an electrically-conductive material that conducts an electrical current. In aspects, the first electrode 115 can be attached to the first major surface 107 and can extend from an interior of the first major surface 107 toward the edge surface 111. For example, the first electrode 115 can extend between a first end, which may be electrically connected to the electronic device, and a second end that may be adjacent to the edge surface 111. As used herein, the term “attached to” can comprise direct attachment and direct contact between a structure (e.g., the first electrode 115, for example) and a surface (e.g., the first major surface 107) of the substrate 103. In addition, the term “attached to” can comprise indirect attachment and non-contact between a structure (e.g., the first electrode 115) and a surface of the substrate 103, for example, when an intermediate structure is located between the structure and the surface of the substrate 103. The first electrode 115 can comprise a metal, such as one or more of aluminum (Al), copper (Cu), gold (Au), nickel (Ni), silver (Ag), molybdenum (Mo), titania (Ti), chromium (Cr), or tin (Sn) or conductive oxides such as one or more of indium tin oxide (ITO), aluminum zinc oxide (AZO), or indium zinc oxide (IZO) or other materials such as carbon nano-tubes (CNT), organic conductors, and electrically conductive inks or pastes.

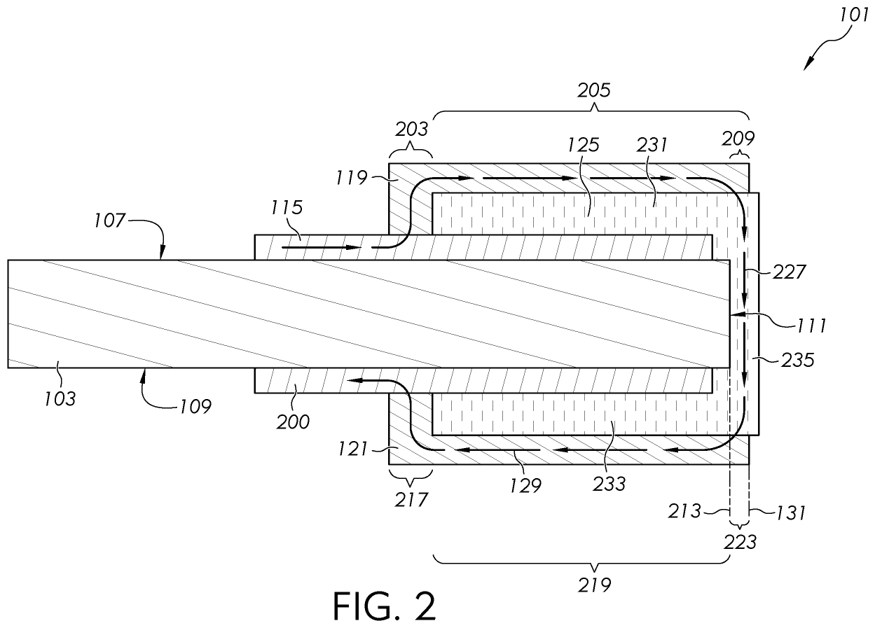

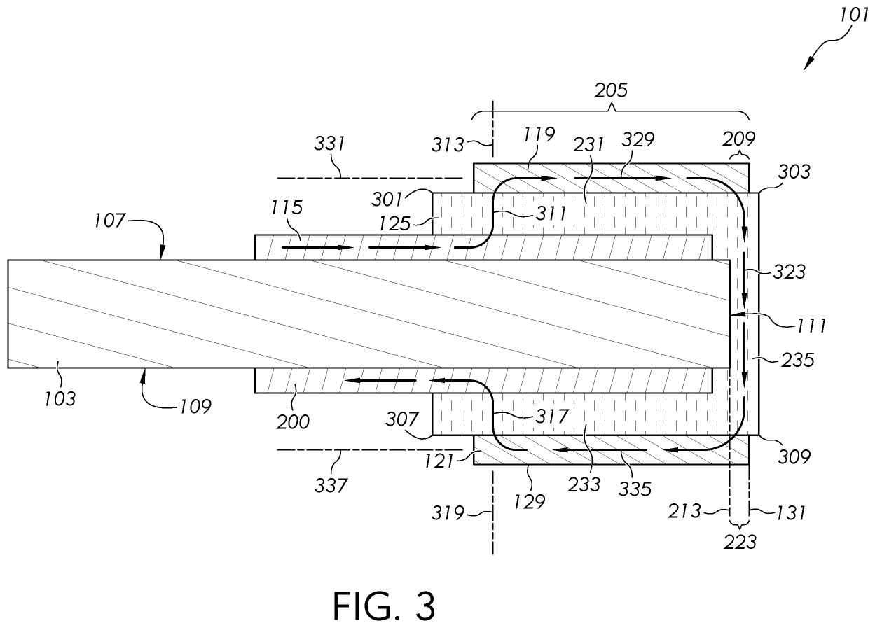

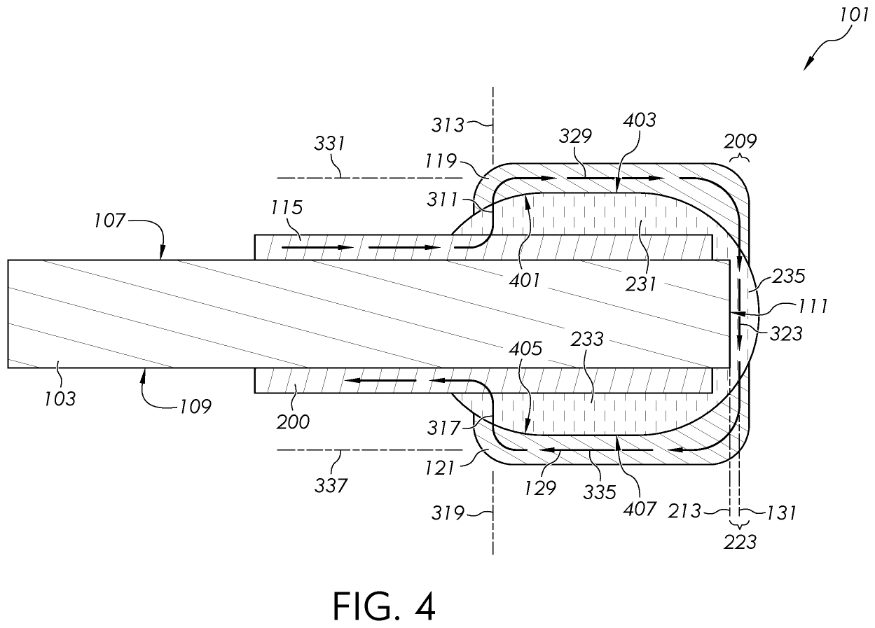

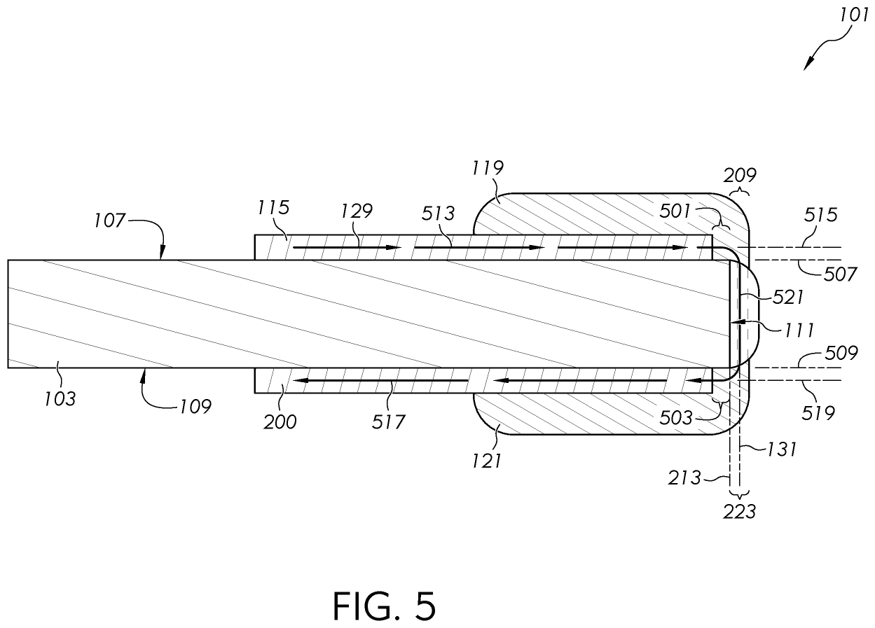

The electronic apparatus 101 comprises one or more surface interconnects, for example, a first surface interconnect 119 and a second surface interconnect 121. The surface interconnects 119, 121 can comprise an electrically-conductive material that conducts an electrical current. For example, the surface interconnects 119, 121 can comprise a metal, such as one or more of aluminum (Al), copper (Cu), gold (Au), nickel (Ni), silver (Ag), molybdenum (Mo), titania (Ti), chromium (Cr), or tin (Sn) or conductive oxides such as one or more of indium tin oxide (ITO), aluminum zinc oxide (AZO), or indium zinc oxide (IZO) or other materials such as carbon nano-tubes (CNT), organic conductors, and electrically conductive inks or pastes. In aspects, the first surface interconnect 119 may be electrically connected to the first electrode 115. By being electrically connected, in aspects, the first surface interconnect 119 may be directly connected to and in contact with the first electrode 115 such as, for example, in the aspects illustrated in FIGS. 2 and 5. In aspects, the first surface interconnect 119 may not be in contact with the first electrode 115 while being electrically connected to the first electrode 115 such as, for example, in the aspects illustrated in FIGS. 3-4. As illustrated in FIGS. 3-4, an intervening electrically-conductive material may be positioned in contact with and between the first surface interconnect 119 and the first electrode 115. The second surface interconnect 121 may be electrically connected to a second electrode (e.g., a second electrode 200 illustrated in FIGS. 2-5). As illustrated in FIGS. 2 and 5, the second surface interconnect 121 may be electrically connected to the second electrode 200 by being in contact with the second electrode 200. If multiple first electrodes 115 and multiple second electrodes 200 exist, they can have the same or different linewidths and/or spacing within the range of about 1 micrometer to about 1000 micrometers or about 5 micrometers to about 500 micrometers or about 10 micrometers to about 200 micrometers. However, as illustrated in FIGS. 3-4, in aspects, an intervening electrically-conductive material may be positioned in contact with and between the second surface interconnect 121 and the second electrode 200. The electrodes 115, 200 and the surface interconnects 119, 121 can comprise an electrical resistivity that may be within a range from about 1.59×10⁸ ρ (Ω·m) at 20° C. to about 1×10⁶ ρ (Ω·m) at 20° C.

As illustrated in FIG. 1, the first surface interconnect 119 and the second surface interconnect 121 may be spaced apart, such that the first surface interconnect 119 is not in contact with the second surface interconnect 121. The electronic apparatus 101 comprises an anisotropic conductor 125 positioned between the first surface interconnect 119 and the second surface interconnect 121 and defining a current path 129 between the first electrode 115 and the second electrode 200. For example, the current path 129 can comprise the path along which a stream of charged particles moves through the electrically-conductive materials 115, 119, 121, 125, 200. The anisotropic conductor 125 can comprise electrically-conductive particles that are positioned in an electrically insulating adhesive layer. The electrically-conductive particles can be arranged along a plurality of axes that may be parallel. For example, a portion of the electrically-conductive particles may be arranged along a first axis 131 such that the current path 129 through the anisotropic conductor 125 can extend along the first axis 131. The anisotropic conductor 125 can be positioned on one or more edge surfaces 111 or substrates 103. If multiple anisotropic conductors are positioned on a substrate 103, these can either have the same optical electrical, and mechanical properties or differ.

The anisotropic conductor 125 can extend substantially continuously along the edge surface 111 and may define a plurality of current paths. For example, the electronic apparatus 101 may comprise a second pair of surface interconnects 141, 143 that are spaced apart from the first surface interconnect 119 and the second surface interconnect 121. The anisotropic conductor 125 can extend between the second pair of surface interconnects 141, 143 such that the anisotropic conductor 125 defines a second current path 145 between the second pair of surface interconnects 141, 143. Another portion of the electrically-conductive particles may be arranged along a second axis 147 such that the second current path 145 through the anisotropic conductor 125 can extend along the second axis 147, wherein the second axis 147 may be substantially parallel to the first axis 131. Additional electrodes and surface interconnects (e.g., a third pair of surface interconnects 151, 153) may be spaced apart along the edge surface 111 of the substrate 103 and can define additional current paths along additional axes (e.g., a third current path 155 along a third axis 157 that is substantially parallel to the first axis 131). The anisotropic conductor 125 comprises differing electrical resistivity in different directions. For example, a first electrical resistance of the anisotropic conductor 125 in a direction perpendicular to the first major surface 107 (e.g., along or parallel to the first axis 131, the second axis 147, or the third axis 157) may be less than about 1 ohm. A second electrical resistance of the anisotropic conductor 125 in a direction parallel to the first major surface 107 (e.g., non-parallel to the first axis 131, the second axis 147, or the third axis 157) may be greater than about 1011 ohms. Accordingly, the current path 129 may be electrically isolated from the second current path 145 and the third current path 155, such that adjacent surface interconnects 119, 141, 151 may be electrically isolated from one another. Along the length, the edge surface 111 may have defects (mechanical or optical as example) such as chipping discontinuity, roughness, or cracks. The anisotropic conductor 125 can cover these defects present in the edge surface 111.

FIGS. 2-5 illustrate a side view of several aspects of the electronic apparatus 101 of FIG. 1. Referring to FIG. 2, the first electrode 115 may be attached to the first major surface 107 and the second electrode 200 may be attached to the second major surface 109. The second electrode 200 may be substantially identical to the first electrode 115. In other aspects, the first electrode and second electrode may differ in composition, thickness, pattern, or electrical properties. The first surface interconnect 119 can extend substantially parallel to the first electrode 115 and may comprise a first interconnect portion 203 and a second interconnect portion 205. The first interconnect portion 203 may be located at a first end of the first surface interconnect 119 and may be in contact with the first electrode 115. The second interconnect portion 205 can be attached to the first interconnect portion 203 and may extend parallel to and spaced apart from the first electrode 115 such that the second interconnect portion 205 may not be in contact with the first electrode 115. The first surface interconnect 119 can comprise a first extension portion 209 that extends beyond an edge plane 213 along which the edge surface 111 extends. For example, the first extension portion 209 may be located at a second end of the first surface interconnect 119 opposite the first interconnect portion 203, such that the first surface interconnect 119 can intersect the edge plane 213. As such, the first extension portion 209 can lie on one side of the edge plane 213 while a remainder of the first surface interconnect 119 can lie on an opposite side of the edge plane 213.

The second surface interconnect 121 can be positioned on an opposite side of the substrate 103 from the first surface interconnect 119 and may be substantially identical to the first surface interconnect 119. For example, the second surface interconnect 121 can extend substantially parallel to the second electrode 200 and may comprise a third interconnect portion 217 and a fourth interconnect portion 219. In other aspects, the first surface interconnect and second surface interconnect may differ in composition, thickness, pattern, or electrical properties. The third interconnect portion 217 may be located at a first end of the second surface interconnect 121 and may be in contact with the second electrode 200. The fourth interconnect portion 219 may be attached to the third interconnect portion 217 and may extend parallel to and spaced apart from the second electrode 200 such that the fourth interconnect portion 219 may not be in contact with the second electrode 200. The second surface interconnect 121 can comprise a second extension portion 223 that extends beyond the edge plane 213. For example, the second extension portion 223 may be located at a second end of the second surface interconnect 121 opposite the third interconnect portion 217 such that the second surface interconnect 121 can intersect the edge plane 213. As such, the second extension portion 223 can lie on one side of the edge plane 213 while a remainder of the second surface interconnect 121 can lie on an opposite side of the edge plane 213.

The anisotropic conductor 125 defines a portion of the current path 129 between the first electrode 115 and the second electrode 200. For example, the anisotropic conductor 125 is attached to the edge surface 111 and extends between the first extension portion 209 and the second extension portion 223 such that a portion 227 of the current path 129 extends substantially perpendicular to the first major surface 107, for example, along the edge surface 111. For example, the portion 227 of the current path 129 can extend through the anisotropic conductor 125 along the first axis 131 between the first extension portion 209 and the second extension portion 223. The first axis 131 may be substantially parallel to the edge plane 213 and may not intersect the substrate 103. As such, due to the arrangement of the electrically-conductive particles within the anisotropic conductor 125, the portion 227 of the current path 129 may be along the first axis 131 that intersects the first extension portion 209 and the second extension portion 223.

The anisotropic conductor 125 can comprise a first anisotropic portion 231, a second anisotropic portion 233, and a third anisotropic portion 235. For example, the first anisotropic portion 231 can extend between the first electrode 115 and the second interconnect portion 205. In such a configuration, the first anisotropic portion 231 separates the first electrode 115 from the second interconnect portion 205 such that a first surface of the first anisotropic portion 231 is in contact with the first electrode 115 and an opposing second surface of the first anisotropic portion 231 is in contact with the second interconnect portion 205. An end of the first anisotropic portion 231 may be bounded by the first interconnect portion 203. The first anisotropic portion 231 can extend between a first end, which is in contact with the first interconnect portion 203, and a second end, which is beyond the edge plane 213. The second anisotropic portion 233 may be substantially similar to the first anisotropic portion 231 and can extend between the second electrode 200 and the fourth interconnect portion 219. For example, the second anisotropic portion 233 can separate the second electrode 200 from the fourth interconnect portion 219 such that a first surface of the second anisotropic portion 233 is in contact with the second electrode 200 and an opposing second surface of the second anisotropic portion 233 is in contact with the fourth interconnect portion 219. An end of the second anisotropic portion 233 may be bounded by the third interconnect portion 217. The second anisotropic portion 233 can extend between a first end, which is in contact with the third interconnect portion 217, and a second end, which is beyond the edge plane 213. The third anisotropic portion 235 can be attached to the edge surface 111 and can extend between the first surface interconnect 119, for example, the first extension portion 209, and the second surface interconnect 121, for example, the second extension portion 223. As such, the first axis 131 can intersect the first extension portion 209, the second extension portion 223, and the third anisotropic portion 235 of the anisotropic conductor 125, with the first axis 131 spaced apart from and not intersecting the substrate 103.

The first electrode 115, the first surface interconnect 119, the anisotropic conductor 125, the second surface interconnect 121, and the second electrode 200 are electrically connected and define the current path 129 from the first major surface 107 to the second major surface 109. For example, electrical current may be conducted along the current path 129 from the first electrode 115, through the first surface interconnect 119, through the third anisotropic portion 235, through the second surface interconnect 121, and to the second electrode 200. However, the electrical current can be reversed and may be conducted along the current path 129 from the second electrode 200, through the second surface interconnect 121, through the third anisotropic portion 235, through the first surface interconnect 119, and to the first electrode 115.

FIG. 3 illustrates the electronic apparatus 101 wherein the first surface interconnect 119 is spaced apart from the first electrode 115 and the second surface interconnect 121 is spaced apart from the second electrode 200. The electronic apparatus 101 comprises the anisotropic conductor 125, which may be substantially identical to the anisotropic conductor illustrated in FIG. 2. For example, the anisotropic conductor 125 of FIG. 3 can comprise the first anisotropic portion 231, the second anisotropic portion 233, and the third anisotropic portion 235. The first anisotropic portion 231 may extend substantially parallel to the first electrode 115 between a first end 301 and a second end 303. The first end 301 may be uncovered and not in contact with the first surface interconnect 119. The first anisotropic portion 231 can extend between the first electrode 115 and the first surface interconnect 119 such that the first surface interconnect 119 is maintained a distance apart from and not in contact with the first electrode 115. The first surface interconnect 119 can comprise the first extension portion 209 that extends beyond the edge plane 213. The second anisotropic portion 233 may extend substantially parallel to the second electrode 200 between a first end 307 and a second end 309. The first end 307 may be uncovered and not in contact with the second surface interconnect 121. The second anisotropic portion 233 can extend between the second electrode 200 and the second surface interconnect 121 such that the second surface interconnect 121 is maintained a distance apart from and not in contact with the second electrode 200. The second surface interconnect 121 can comprise the second extension portion 223 that extends beyond the edge plane 213.

The current path 129 through the first electrode 115, the first anisotropic portion 231, the first surface interconnect 119, the third anisotropic portion 235, the second surface interconnect 121, the second anisotropic portion 233, and the second electrode 200 can comprise a plurality of path portions. For example, the first anisotropic portion 231 can electrically connect the first electrode 115 and the first surface interconnect 119 by defining a first path portion 311 of the current path 129 that is substantially perpendicular to the first major surface 107. For example, due to the arrangement of the electrically-conductive particles within the anisotropic conductor 125, the first path portion 311 may extend along a first path axis 313 that is substantially parallel to the first axis 131 and substantially perpendicular to the first major surface 107. The first path axis 313 may intersect the first electrode 115, the first anisotropic portion 231, and the first surface interconnect 119. The second anisotropic portion 233 can electrically connect the second electrode 200 and the second surface interconnect 121 by defining a second path portion 317 of the current path 129 that is substantially perpendicular to the second major surface 109. Due to the arrangement of the electrically-conductive particles within the anisotropic conductor 125, the second path portion 317 may extend along a second path portion 317 that is substantially parallel to the first path axis 313 and substantially perpendicular to the second major surface 109. The second path portion 317 may intersect the second electrode 200, the second anisotropic portion 233, and the second surface interconnect 121.

The third anisotropic portion 235 can electrically connect the first surface interconnect 119 and the second surface interconnect 121 by defining a third path portion 323 of the current path 129 substantially perpendicular to the first major surface 107. The third path portion 323 may extend along the first axis 131 that is substantially parallel to the first path axis 313. The remaining portions of the current path 129 can extend through the first surface interconnect 119 and the second surface interconnect 121. For example, the first surface interconnect 119 can define a fourth path portion 329 of the current path 129 that is substantially parallel to the first major surface 107 between the first path portion 311 and the third path portion 323. The fourth path portion 329 can extend along a fourth path axis 331 that is substantially perpendicular to the first axis 131 and substantially parallel to the first major surface 107. Due to the anisotropic conductor 125 acting as an electrical insulator in a direction that is parallel to the fourth path axis 331 (e.g., between the first end 301 and the second end 303 of the first anisotropic portion 231), the fourth path portion 329 may extend through the first surface interconnect 119 and not the first anisotropic portion 231. The second surface interconnect 121 can define a fifth path portion 335 of the current path 129 that is substantially parallel to the second major surface 109 between the second path portion 317 and the third path portion 323. The fifth path portion 335 can extend along a fifth path axis 337 that is substantially perpendicular to the second path axis 319 and substantially parallel to the second major surface 109. Due to the anisotropic conductor 125 acting as an electrical insulator in a direction that is parallel to the fifth path axis 337 (e.g., between the first end 307 and the second end 309 of the second anisotropic portion 233), the fifth path portion 335 may extend through the second surface interconnect 121 and not the second anisotropic portion 233. As such, the first electrode 115, the first surface interconnect 119, the anisotropic conductor 125, the second surface interconnect 121, and the second electrode 200 are electrically connected and define the current path 129 from the first major surface 107 to the second major surface 109. For example, electrical current may be conducted from the first electrode 115, through the first anisotropic portion 231 along the first path portion 311, through the first surface interconnect 119 along the fourth path portion 329, through the third anisotropic portion 235 along the third path portion 323, through the second surface interconnect 121 along the fifth path portion 335, through the second anisotropic portion 233 along the second path portion 317, and to the second electrode 200. Likewise, the electrical current can be reversed from the second electrode 200 to the first electrode 115.

FIG. 4 illustrates the electronic apparatus 101 wherein the anisotropic conductor 125 comprises one or more non-planar surfaces. The electronic apparatus 101 is similar to FIG. 3 and may comprise the first surface interconnect 119 spaced apart from the first electrode 115 and the second surface interconnect 121 spaced apart from the second electrode 200. The first anisotropic portion 231 extends between the first surface interconnect 119 and the first electrode 115, and the second anisotropic portion 233 extends between the second surface interconnect 121 and the second electrode 200. The third anisotropic portion 235 may extend between the first extension portion 209 and the second extension portion 223 such that the third anisotropic portion 235 electrically connects the first surface interconnect 119 and the second anisotropic portion 233.

In aspects, the first surface interconnect 119 comprises a first surface 401 attached to the first anisotropic portion 231, wherein the first surface 401 can comprise a non-planar shape. For example, the first anisotropic portion 231 can comprise a first anisotropic surface 403 that is attached to the first anisotropic portion 231, and the first anisotropic surface 403 can comprise a non-planar shape. The non-planar shape of the first surface 401 can substantially match the non-planar shape of the first anisotropic surface 403. For example, when the first surface 401 comprises a convex shape, the first anisotropic surface 403 can comprise a concave shape. Likewise, when the first surface 401 comprises a concave shape, the first anisotropic surface 403 can comprise a convex shape. The second surface interconnect 121 and the second anisotropic portion 233 can comprise a substantially similar shape as the first surface interconnect 119 and the first anisotropic portion 231. For example, the second surface interconnect 121 comprises a second surface 405 attached to the second anisotropic portion 233, wherein the second surface 405 can comprise a non-planar shape. The second anisotropic portion 233 can comprise a second anisotropic surface 407 that is attached to the second anisotropic portion 233, and the second anisotropic surface 407 can comprise a non-planar shape. The non-planar shape of the second surface 405 can substantially match the non-planar shape of the second anisotropic surface 407. For example, when the second surface 405 comprises a convex shape, then the second anisotropic surface 407 can comprise a concave shape. Likewise, when the second surface 405 comprises a concave shape, then the second anisotropic surface 407 can comprise a convex shape. The surfaces 401, 403, 405, 407 can comprise a curved or rounded shape that gradually deviates from being straight. The anisotropic conductor 125 electrically connects the first electrode 115 and the second electrode 200 via the first extension portion 209 and the second extension portion 223.

FIG. 5 illustrates the electronic apparatus 101 wherein the anisotropic conductor 125 is spaced a distance apart from the first electrode 115 and the second electrode 200 such that the anisotropic conductor 125 is not in contact with the first electrode 115 or the second electrode 200. For example, the first surface interconnect 119 can be attached to and in contact with the first electrode 115, with the first surface interconnect 119 extending substantially parallel and adjacent to the first electrode 115. As such, the anisotropic conductor 125 may not be positioned between the first surface interconnect 119 and the first electrode 115. Similarly, the second surface interconnect 121 can be attached to and in contact with the second electrode 200, with the second surface interconnect 121 extending substantially parallel and adjacent to the second electrode 200. As such, the anisotropic conductor 125 may not be positioned between the second surface interconnect 121 and the second electrode 200. The anisotropic conductor 125 is attached to the edge surface 111 and spaced a first distance 501 apart from the first electrode 115. For example, the first extension portion 209 may lie between the anisotropic conductor 125 and the first electrode 115 along the current path 129. The anisotropic conductor 125 is spaced a second distance 503 apart from the second electrode 200. As such, the second extension portion may lie between the anisotropic conductor 125 and the second electrode 200 along the current path 129.

The application of the anisotropic conductor 125 to the substrate 103 may be localized to the edge surface 111 such that the anisotropic conductor 125 may not contact the first major surface 107 or the second major surface 109. For example, the first major surface 107 can extend along a first major surface plane 507 and the second major surface 109 can extend along a second major surface plane 509. When the anisotropic conductor 125 is attached to the edge surface 111 and is not in contact with the first major surface 107 or the second major surface 109, the anisotropic conductor 125 may be located between the first major surface plane 507 and the second major surface plane 509, with the anisotropic conductor 125 not intersecting the first major surface plane 507 or the second major surface plane 509. The anisotropic conductor 125 may contact the first major surface 107 or the second major surface 109 while still being spaced apart and not in contact with the first electrode 115 or the second electrode 200. For example, the anisotropic conductor 125 may intersect one or both of the first major surface plane 507 or the second major surface plane 509 but may be spaced apart from the first electrode 115 and the second electrode 200. As such, the first extension portion 209 may be located between the anisotropic conductor 125 and the first electrode 115, and the second extension portion 223 may be located between the anisotropic conductor 125 and the second electrode 200.

The anisotropic conductor 125 electrically connects the first electrode 115 and the second electrode 200 via the first extension portion 209 and the second extension portion 223. The current path 129 may comprise a plurality of path portions, for example, a first path portion 513, a second path portion 517, and a third path portion 521. The first path portion 513 can extend through the first electrode 115 and the first extension portion 209 along a first path axis 515. The first path axis 515 can be substantially parallel to the first major surface 107. The second path portion 517 can extend through the second electrode 200 and the second extension portion 223 along a second path axis 519. The second path axis 519 can be substantially parallel to the second major surface 109 and the first path axis 515. The anisotropic conductor 125 electrically connects the first extension portion 209 and the second extension portion 223, with the third path portion 521 extending through the anisotropic conductor 125 between the first extension portion 209 and the second extension portion 223. The third path portion 521 extends between the first path portion 513 and the second path portion 517, with the third path portion 521 extending along the first axis 131. Due to the arrangement of the electrically-conductive particles within the anisotropic conductor 125, the first axis 131 may be substantially perpendicular to the first path axis 515 and the second path axis 519.

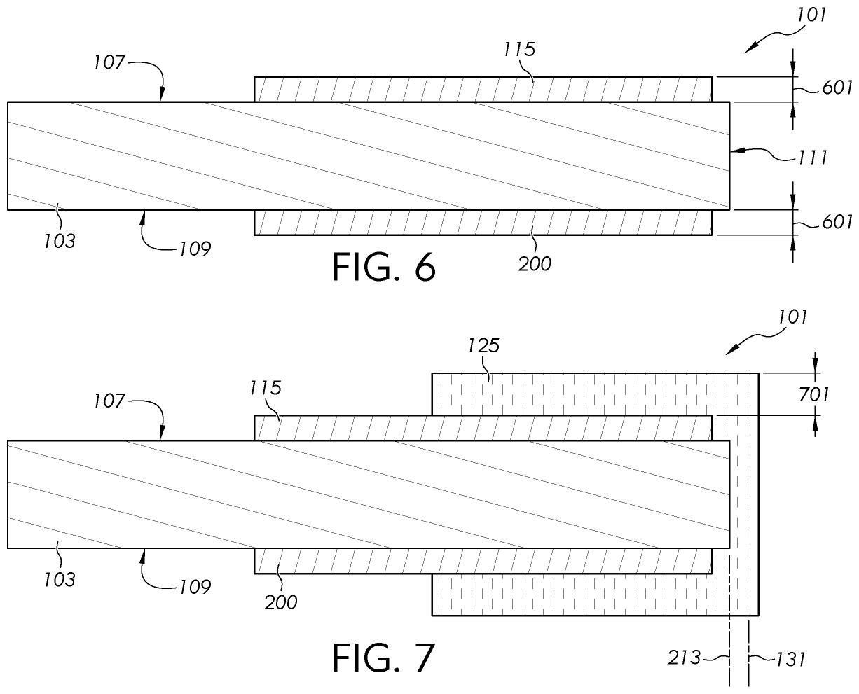

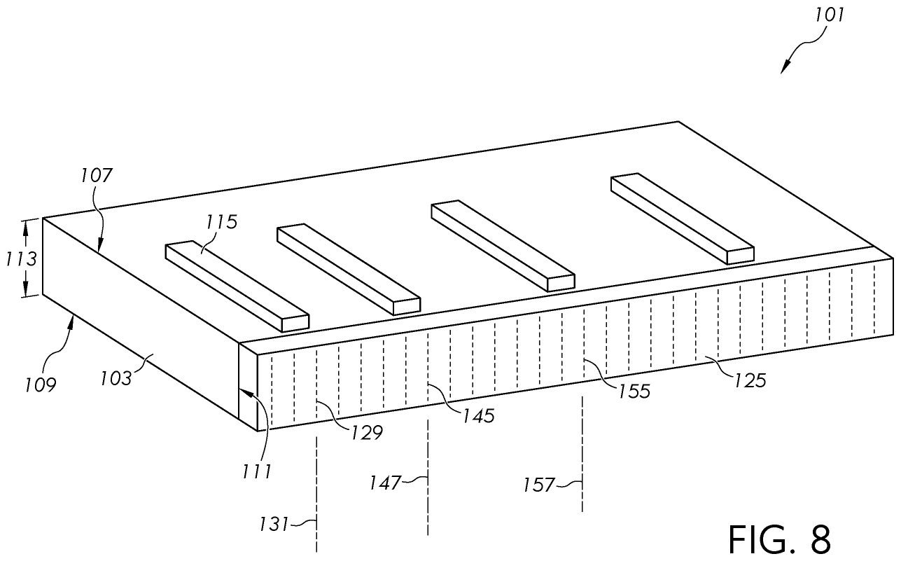

FIGS. 6-10 illustrate methods of manufacturing the electronic apparatus 101. Referring to FIG. 6, methods can comprise forming the first electrode 115 on the first major surface 107 of the substrate 103 and forming the second electrode 200 on the second major surface of the substrate 103. The first electrode 115 and the second electrode 200 can comprise a thickness 601 that is within a range from about 0.1 micrometers (μm) to about 20 μm. The first electrode 115 and the second electrode 200 can be formed in several ways, for example, by a vacuum deposition process, a metal plating process, or a printing process. In aspects, a plurality of first electrodes 115 can be formed on the first major surface 107 and a plurality of second electrodes 200 can be formed on the second major surface 109 (e.g., as illustrated in FIGS. 1 and 8). For example, the first electrodes 115 can be spaced apart along the first major surface 107 and separated a distance that is within a range from about 0.01 micrometers to about 1000 micrometers. The second electrodes 200 can be spaced apart along the second major surface 109 and separated a distance that is within a range from about 0.01 micrometers to about 1000 micrometers. The first electrode and second electrode may differ in composition, thickness, pattern, or electrical properties.

Referring to FIG. 7, methods can comprise forming the anisotropic conductor 125 on the edge surface 111 of the substrate 103. The anisotropic conductor 125 can comprise a thickness 701 that is within a range from about 0.05 μm to about 1000 μm, or within a range from about 1 μm to about 20 μm. The anisotropic conductor 125 can comprise a liquid or semi-liquid solution or paste coating that can be applied to the substrate 103 in several ways. For example, the anisotropic conductor 125 can be formed by a dip coating process, a screen-printing process, an ink-jet printing process, a molding process, a stencil printing process, a dispensing process such as syringe, a solution coating process, a printing process, such as pad, flexo, gravure, etc. After applying the anisotropic conductor 125, the electrically-conductive particles of the anisotropic conductor 125 can be aligned, for example, by applying a magnetic field, electric field, or mechanical force to the anisotropic conductor 125 causing the electrically-conductive particles to align in a desired direction. Following the alignment of the electrically-conductive particles, the anisotropic conductor 125 can be cured, for example, by thermally-curing or UV-curing the anisotropic conductor 125 or other method to fix the alignment of the conductive particles. The anisotropic conductor attributes such as thickness, pattern, shape, surface roughness, optical, and conductor alignment may differ in portions associated with surfaces 107, 109, and 111. As shown in FIG. 8, the anisotropic conductor 125 can have a substantially uniform cross-section along the length of edge surface 111. Alternatively, the anisotropic conductor 125 can be patterned or segmented along the length of the edge surface. In addition to serving as an electrical conductor, the anisotropic conductor 125 can serve as an optical material and mechanical protection layer. The anisotropic conductor 125 can be optically transparent, absorbing, or scattering. The anisotropic conductor 125 can serve as a mechanical protection layer to prevent mechanical damage to the substrate 103 and edge surface 111. The mechanical protection of the anisotropic conductor 125 is contributed to by a Youngs modulus value<50 GPa, <20 GPa, <10 GPa, or <1 GPa.

Forming the anisotropic conductor 125 can comprise generating a first electrical resistance of the anisotropic conductor 125 in a direction perpendicular to the first major surface 107 that is less than about 5 ohms, for example less than about 1 ohm, and a second electrical resistance of the anisotropic conductor 125 in a direction parallel to the first major surface 107 that is greater than about 10⁹ ohs, for example, greater than about 10¹¹ ohms. By aligning the electrically-conductive particles, a variable electrical resistance within the anisotropic conductor 125 can be generated. For example, the electrically-conductive particles may be aligned along the first axis 131 and along axes that are parallel to the first axis 131, such that the first electrical resistance along axes parallel to the first axis 131 is less than about 1 ohm. The electrically-conductive particles aligned along the axes may be spaced apart in a direction that is perpendicular to the axes, such that the second electrical resistance in a direction perpendicular to the first axis 131 (e.g., parallel to the first major surface 107) is greater than about 10¹¹ ohms. As such, the anisotropic conductor 125 can define a current path in a direction parallel to the first axis 131.

FIG. 8 illustrates the electronic apparatus 101 following the formation of the anisotropic conductor 125. In aspects, the anisotropic conductor 125 can be formed on the edge surface 111 while not overlapping or contacting the first major surface 107 or the second major surface 109. As illustrated in FIG. 8, the anisotropic conductor 125 can be formed to extend along the edge surface 111. In aspects, to reduce the manufacturing time of the electronic apparatus 101, the anisotropic conductor 125 can be applied to the entire edge surface 111 atone time. Upon applying the anisotropic conductor 125, the electrically-conductive particles may be aligned along the parallel axes 131, 147, 157, followed by curing (e.g., via thermal, UV, etc.) of the anisotropic conductor 125. While FIG. 8 illustrates the anisotropic conductor 125 as being attached to the edge surface 111 but not contacting the first major surface 107 or the second major surface 109, the anisotropic conductor 125 can be formed in any of the configurations illustrated in FIGS. 2-5. For example, referring to FIG. 7, the anisotropic conductor 125 can be formed across the entire edge surface 111 covering the first major surface 107 and the second major surface 109. In aspects, the anisotropic conductor 125 can be formed with the rounded, non-planar anisotropic surface 403, 407 (e.g., illustrated in FIG. 4) or with the substantially planar surfaces of FIGS. 2-3. As shown in FIG. 8, the first electrode 115 and second electrode 200 can have a substantially similar shape from electrode-to-electrode along the length of edge surface 111. Alternatively, these electrodes can have a varying shape from electrode-to-electrode depending on the device electrical requirements.

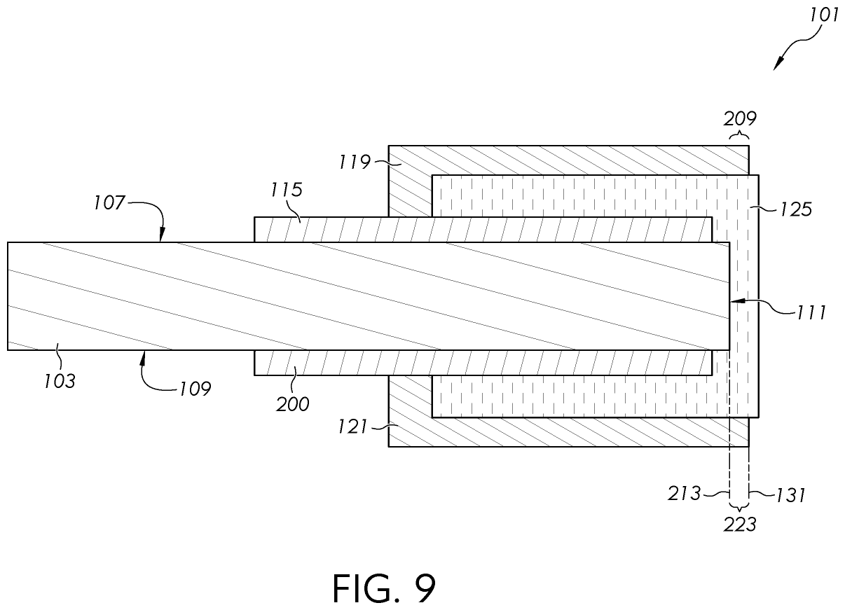

Referring to FIG. 9, methods can comprise forming the first surface interconnect 119 electrically connected to the first electrode 115 such that the first extension portion 209 of the first surface interconnect 119 extends beyond the edge plane 213 along which the edge surface 111 extends. Methods can comprise forming the second surface interconnect 121 electrically connected to the second electrode 200 such that the second extension portion 223 of the second surface interconnect 121 extends beyond the edge plane 213. The first surface interconnect 119 and the second surface interconnect 121 can be formed in several ways, for example, via shadow mask deposition of a conductive material, sputtering, evaporation, a printing process (e.g., ink jet printing, aerosol jet printing, etc.), a plating process, etc. The first surface interconnect 119 and the second surface interconnect 121 may differ in composition, thickness, pattern, or electrical properties. Forming the first surface interconnect 119 can comprise contacting the first surface interconnect 119 to the first electrode 115, and forming the second surface interconnect 121 can comprise contacting the second surface interconnect 121 to the second electrode 200. For example, similar to FIGS. 2 and 5, portions of the first surface interconnect 119 and the second surface interconnect 121 can be formed to contact the first electrode 115 and the second electrode 200, respectively. The anisotropic conductor 125 can electrically connect the first extension portion 209 and the second extension portion 223 such that the current path 129 extending through the anisotropic conductor 125 is substantially perpendicular to the first major surface 107. As shown in FIG. 1, the first surface interconnect 119 and the second surface interconnect 121 can have a substantially similar shape from electrode-to-electrode along the length of the edge surface 111. Alternatively, these electrodes can have a varying shape from electrode-to-electrode depending on the device electrical requirements.

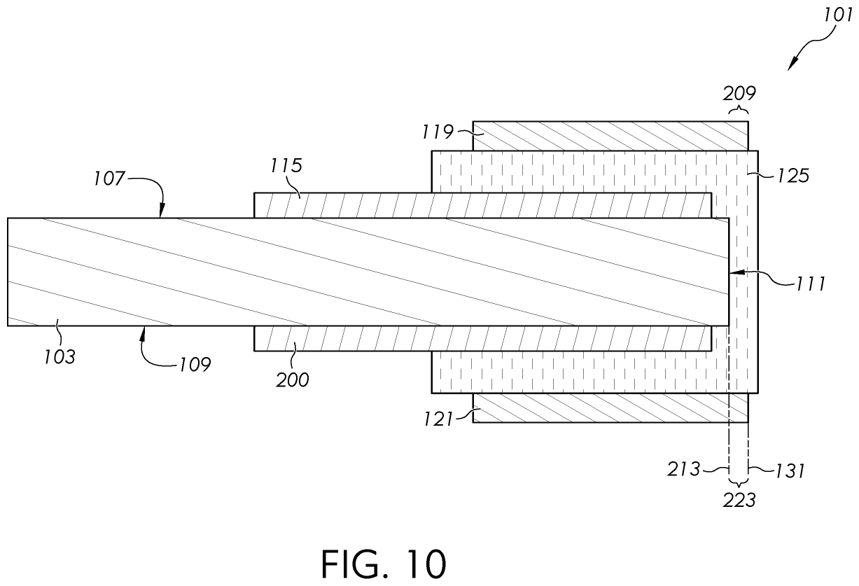

Referring to FIG. 10, the first surface interconnect 119 and the second surface interconnect 121 are not limited to being formed in contact with the electrodes 115, 200. For example, similar to FIGS. 3-4, forming the first surface interconnect 119 can comprise maintaining a space between the first surface interconnect 119 and the first electrode 115 such that the first surface interconnect 119 is not in contact with the first electrode 115 and the first anisotropic portion 231 extends between the first electrode 115 and the first surface interconnect 119. Similarly, forming the second surface interconnect 121 can comprise maintaining a space between the second surface interconnect 121 and the second electrode 200 such that the second surface interconnect 121 is not in contact with the second electrode 200 and the first anisotropic portion 231 extends between the second electrode 200 and the second surface interconnect 121. Accordingly, the surface interconnects 119, 121 can be formed in several ways, for example, in contact with the electrodes 115, 200 (e.g., as illustrated in FIGS. 2, 5, and 9) and spaced apart from the electrodes 115, 200 (e.g., as illustrated in FIGS. 3, 4, and 10). The electrodes 115, 200 may differ in composition, thickness, pattern, or electrical properties.

The electronic apparatus 101 provides several benefits that reduce manufacturing time of the electronic apparatus and improve performance. For example, the anisotropic conductor 125 can be formed to extend along the entire edge surface 111 followed by magnetically aligning and forming conductive paths within the anisotropic conductor 125. As such, the anisotropic conductor 125 can function as a wraparound electrode that can provide a conductive path between the major surfaces 107, 109, while electrically isolating adjacent electrodes and surface interconnects. The formation of the anisotropic conductor 125 is a parallel process that is quick and reliable as compared to wraparound electrodes that are formed and patterned in a serial process (e.g., step by step). In addition, the anisotropic conductor 125 can electrically isolate adjacent current paths (e.g., 129, 145, 155 of FIGS. 1 and 8) around the edge surface 111, which can allow for a reduced spacing between adjacent current paths. For example, as illustrated in FIGS. 1 and 8, the current paths 129, 145, 155 can be spaced apart a distance that may be about 50 microns or less. Further, the anisotropic conductor 125 can form a conductive path between the major surfaces 107, 109 without the use of a via (e.g., an opening) through the substrate 103, which can reduce manufacturing time of the electronic apparatus 101.

It should be understood that while various aspects have been described in detail relative to certain illustrative and specific examples thereof, the present disclosure should not be considered limited to such, as numerous modifications and combinations of the disclosed features are possible without departing from the scope of the following claims.

1. An electronic apparatus comprising:
a substrate comprising a first major surface, a second major surface, and an edge surface extending between the first major surface and the second major surface;
a first electrode attached to the first major surface;
a second electrode attached to the second major surface;
a first surface interconnect electrically connected to the first electrode and comprising a first extension portion extending beyond an edge plane along which the edge surface extends;
a second surface interconnect electrically connected to the second electrode and comprising a second extension portion extending beyond the edge plane; and
an anisotropic conductor defining a current path between the first electrode and the second electrode, the anisotropic conductor attached to the edge surface and extending between the first extension portion and the second extension portion such that the current path extends along the first major surface, the edge surface, and the second major surface.

2. The electronic apparatus of claim 1, wherein the current path is spaced apart from the substrate and intersects the first extension portion, the second extension portion, and the anisotropic conductor.

3. The electronic apparatus of claim 2, wherein the substrate comprises a thickness between the first major surface and the second major surface within a range from about 0.1 mm to about 1 mm.

4. The electronic apparatus of claim 1, wherein the anisotropic conductor is spaced a first distance apart from the first electrode such that the first extension portion lies between the anisotropic conductor and the first electrode along the current path.

5. The electronic apparatus of claim 4, wherein the anisotropic conductor is spaced a second distance apart from the second electrode such that the second extension portion lies between the anisotropic conductor and the second electrode along the current path.

6. The electronic apparatus of claim 1, wherein the first surface interconnect is spaced apart from the first electrode, and a first anisotropic portion of the anisotropic conductor extends between the first electrode and the first surface interconnect, the first anisotropic portion electrically connecting the first electrode and the first surface interconnect by defining a first path portion of the current path substantially perpendicular to the first major surface.

7. The electronic apparatus of claim 6, wherein the second surface interconnect is spaced apart from the second electrode, and a second anisotropic portion of the anisotropic conductor extends between the second electrode and the second surface interconnect, the second anisotropic portion electrically connecting the second electrode and the second surface interconnect by defining a second path portion of the current path substantially perpendicular to the second major surface.

8. The electronic apparatus of claim 1, wherein the first surface interconnect comprises a first interconnect portion in contact with the first electrode and a second interconnect portion extending parallel to and spaced apart from the first electrode, a first anisotropic portion of the anisotropic conductor extending between the first electrode and the second interconnect portion.

9. The electronic apparatus of claim 8, wherein the second surface interconnect comprises a third interconnect portion in contact with the second electrode and a fourth interconnect portion extending parallel to and spaced apart from the second electrode, a second anisotropic portion of the anisotropic conductor extending between the second electrode and the fourth interconnect portion.

10. The electronic apparatus of claim 1, wherein a first electrical resistance of the anisotropic conductor in a direction perpendicular to the first major surface is less than about 1 ohm.

11. The electronic apparatus of claim 10, wherein a second electrical resistance of the anisotropic conductor in a direction parallel to the first major surface is greater than about 10¹¹ ohms.

12. An electronic apparatus comprising:
a substrate comprising a first major surface, a second major surface, and an edge surface extending between the first major surface and the second major surface;
a first electrode attached to the first major surface;
a second electrode attached to the second major surface;
a first surface interconnect extending parallel to and spaced apart from the first electrode;
a second surface interconnect extending parallel to and spaced apart from the second electrode; and
an anisotropic conductor defining a current path between the first electrode and the second electrode, the anisotropic conductor comprising:
a first anisotropic portion extending between the first electrode and the first surface interconnect, the first anisotropic portion electrically connecting the first electrode and the first surface interconnect by defining a first path portion of the current path substantially perpendicular to the first major surface;
a second anisotropic portion extending between the second electrode and the second surface interconnect, the second anisotropic portion electrically connecting the second electrode and the second surface interconnect by defining a second path portion of the current path substantially perpendicular to the second major surface; and
a third anisotropic portion attached to the edge surface and extending between the first surface interconnect and the second surface interconnect, the third anisotropic portion electrically connecting the first surface interconnect and the second surface interconnect by defining a third path portion of the current path along the edge surface.

13. The electronic apparatus of claim 12, wherein the first surface interconnect comprises a first surface attached to the first anisotropic portion.

14. The electronic apparatus of claim 12, wherein the first surface interconnect defines a fourth path portion of the current path substantially parallel to the first major surface between the first path portion and the third path portion, and the second surface interconnect defines a fifth path portion of the current path substantially parallel to the second major surface between the second path portion and the third path portion.

15. The electronic apparatus of claim 12, wherein the first surface interconnect comprises a first extension portion extending beyond an edge plane along which the edge surface extends and the second surface interconnect comprises a second extension portion extending beyond the edge plane.

16. The electronic apparatus of claim 15, wherein the third anisotropic portion extends between the first extension portion and the second extension portion such that an axis intersects the first extension portion, the second extension portion, and the third anisotropic portion, the axis spaced apart from the substrate.

17. A method of manufacturing an electronic apparatus comprising:
forming a first electrode on a first major surface of a substrate;
forming a second electrode on a second major surface of the substrate;
forming an anisotropic conductor on an edge surface of the substrate;
forming a first surface interconnect electrically connected to the first electrode such that a first extension portion of the first surface interconnect extends beyond an edge plane along which the edge surface extends; and
forming a second surface interconnect electrically connected to the second electrode such that a second extension portion of the second surface interconnect extends beyond the edge plane, the anisotropic conductor electrically connecting the first extension portion and the second extension portion such that a current path extends through the anisotropic conductor is substantially perpendicular to the first major surface.

18. The method of claim 17, wherein forming the anisotropic conductor comprises forming a first electrical resistance of the anisotropic conductor in a direction perpendicular to the first major surface less than about 1 ohm and a second electrical resistance of the anisotropic conductor in a direction parallel to the first major surface greater than about 10¹¹ ohms.

19. The method of claim 17, wherein forming the first surface interconnect comprises maintaining a space between the first surface interconnect and the first electrode such that the first surface interconnect is not in contact with the first electrode and a first anisotropic portion of the anisotropic conductor extends between the first electrode and the first surface interconnect.

20. The method of claim 17, wherein forming the first surface interconnect comprises contacting the first surface interconnect to the first electrode.
